(19) United States
(12) Patent Application Publication
(10) Pub. No.: US 2026/0191123 A1
(43) Pub. Date: Jul. 2, 2026

(54) MANUFACTURE METHOD FOR A PACKAGING SUBSTRATE

(71) Applicant: Absolics Inc., Covington, GA (US)

(72) Inventors: SI HUN LEE, Covington, GA (US); Younggyu LEE, Covington, GA (US)

(73) Assignee: Absolics Inc., Covington, GA (US)

(21) Appl. No.: 19/344,487

(22) Filed: Sep. 29, 2025

Related U.S. Application Data
(60) Provisional application No. 63/739,108, filed on Dec. 26, 2024.

(51) Int. Cl. H01L 21/48; H01L 21/56

(52) U.S. Cl. CPC H10W 99/00; H10W 74/01

(57) ABSTRACT

A method of manufacturing a packaging substrate according to the present disclosure comprises: a preparation step of preparing a preliminary substrate which comprises a core layer in which a cavity portion comprises a device mounting space and an inner side surface of the cavity surrounding the device mounting space; a surface treatment step of increasing surface energy of at least a portion of the inner side surface of the cavity; and an encapsulation layer forming step of forming an encapsulation layer which comprises surrounding at least a portion of the surface of the device portion with an encapsulation layer-forming composition, thereby manufacturing the packaging substrate.

In this case, defects that may occur in a process of forming the encapsulation layer and an insulating layer in the packaging substrate may be effectively suppressed.

### TECHNICAL FIELD

The present disclosure relates to a manufacture method for a packaging substrate.

### BACKGROUND ART

In manufacturing electronic components, implementing circuits on a semiconductor wafer is called the front-end process (FE), and assembling the wafer into a state that can actually be used in a product is called the back-end process (BE), and the packaging process is included in this back-end process.

Recently, four core technologies of the semiconductor industry that enabled the rapid development of electronic products are semiconductor technology, semiconductor packaging technology, manufacturing process technology, and software technology. Semiconductor technology has been developed in various forms, such as line width in sub-micron or nano units, more than tens of millions of cells, high-speed operation, and large heat dissipation, but relatively, the technology for perfectly packaging them has not been supported. Accordingly, the electrical performance of semiconductors may be determined by the packaging technology and the electrical connection according to the packaging rather than the performance of the semiconductor technology itself.

As materials of packaging substrates, ceramic or resin is applied. In the case of a ceramic substrate, it has high resistance value or high dielectric constant, and thus it is not easy to mount high-performance high-frequency semiconductor devices. In the case of a resin substrate, relatively high-performance high-frequency semiconductor devices may be mounted, but there is a limit to reducing the wiring pitch.

Recently, studies applying silicon or glass as high-end packaging substrates are in progress. In a silicon or glass substrate, through holes are formed and a conductive material is applied to the through holes, so that the wiring length between the device and the motherboard becomes short and excellent electrical characteristics may be obtained.

### PRIOR ART LITERATURE

### Patent Literature

Korean Patent Publication No. 10-2021-0127188

### DISCLOSURE OF THE INVENTION

### Problems to be Solved

An object of the present disclosure is to provide a manufacture method for a packaging substrate capable of effectively suppressing defects generated in the process of forming an encapsulation layer and an insulating layer in the packaging substrate.

### Means for Solving the Problems

A manufacture method for a packaging substrate according to one embodiment of the present specification comprises:
a preparation step of preparing a preliminary substrate including a core layer in which a cavity portion including a device mounting space and an inner side surface of the cavity surrounding the device mounting space is formed;
a surface treatment step of increasing surface energy of at least a portion of the inner side surface of the cavity; and
an encapsulation layer forming step of forming an encapsulation layer surrounding at least a portion of the surface of the device portion with an encapsulation layer-forming composition,
thereby manufacturing a packaging substrate.

The preliminary substrate may further include a cavity conductive layer formed on the inner side surface of the cavity.

The inner side surface of the cavity may include an exposed region not covered by the cavity conductive layer.

In the surface treatment step, the surface energy of the cavity conductive layer and the exposed region may be increased.

In the surface treatment step, at least a portion of the inner side surface of the cavity may be plasma-treated.

In the surface treatment step, the cavity conductive layer and the exposed region may be plasma-treated.

In the surface treatment step, an ambient gas may include 50 vol % or more of oxygen gas.

In the surface treatment step, plasma power may be 50 W to 1500 W.

The surface treatment step may be carried out for 15 seconds to 60 seconds.

In the surface treatment step, plasma treatment may be performed with 50 sccm to 1000 sccm of ambient gas.

In the surface treatment step, a contact angle of water to the inner side surface of the cavity may be adjusted to 60° or less.

The manufacture method for a packaging substrate may further include a device mounting step of mounting a device portion in the cavity portion after the surface treatment step.

The device portion may include a side surface disposed apart from the inner side surface of the cavity.

A gap aspect ratio Arg of Equation 1 below may be 30 or less.

$$Arg = \frac{e h}{g} \qquad [ Equation 1 ]$$

In Equation 1, eh is a height of the device portion, and g is a minimum distance between a first point located on a side surface of the device portion and a second point located on the inner side surface of the cavity.

The g value may be 20 μm to 500 μm.

A viscosity of the encapsulation layer-forming composition at 25° C. may be 12,000 cps to 38,000 cps.

The encapsulation layer-forming composition may include 45 wt % or more and 80 wt % or less of filler.

### Effects of the Invention

The manufacture method for a packaging substrate of the present disclosure may effectively suppress the generation of defects in the process of forming an encapsulation layer and an insulating layer in the packaging substrate.

### BRIEF DESCRIPTION OF THE DRAWINGS

FIG. 1 is a cross-sectional view illustrating a preliminary substrate prepared through a preparation step of the present disclosure.

FIG. 2 is a cross-sectional view illustrating a preliminary substrate prepared through a device mounting step of the present disclosure.

FIG. 3 is a cross-sectional view illustrating a packaging substrate prepared through an encapsulation layer forming step of the present disclosure.

### DETAILED DESCRIPTION FOR EMBODYING THE INVENTION

Hereinafter, exemplary embodiments will be described in detail with reference to the accompanying drawings so that those skilled in the art to which the present invention pertains may easily carry out the invention. However, the present invention may be implemented in various different forms and is not limited to the embodiments described herein. Throughout the specification, the same reference numerals are assigned to similar parts.

Throughout this specification, the term “a combination thereof” included in a Markush-type expression means a mixture or combination of one or more selected from the group of elements described in the Markush-type expression, and means that one or more selected from the group of the elements are included.

Throughout this specification, terms such as “first,” “second,” or “A,” “B,” are used to distinguish the same terms from each other. In addition, unless the singular expression clearly means otherwise in the context, the singular expression includes the plural expression.

In this specification, “˜ based” may mean that the compound contains a compound corresponding to “˜” and/or a derivative of “˜” in the compound.

In this specification, the meaning that B is located on A means not only that B is located directly on A but also that another layer is interposed between them, and thus B is located on A. It is not limitedly interpreted that B is located in direct contact with the surface of A.

In this specification, the meaning that B is connected to A means that A and B are directly connected or connected through another component between A and B, and unless otherwise specified, it is not limitedly interpreted that A and B are directly connected.

In this specification, a singular expression is interpreted to include both singular and plural as interpreted in the context unless there is a special description.

In this specification, shapes, relative sizes, angles, etc., of each component in the drawings may be exaggerated for illustration purposes, and rights are not limitedly interpreted to the drawings.

In this specification, that A and B are adjacent means that A and B are in contact with each other or located close to each other without contact. The expression that A and B are adjacent is not limitedly interpreted as A and B being in contact with each other unless otherwise specified.

In this specification, unless otherwise specified, property values of each component in the packaging substrate are interpreted as those measured at room temperature. Room temperature is 20° C. to 25° C.

After a device is mounted in a cavity in the core layer, defects may occur during the process of encapsulating the device. Specifically, voids may occur in the encapsulation layer surrounding the device, or undulation may occur in an insulating layer formed on the encapsulation layer. Such a phenomenon may more frequently occur when a conductive layer is implemented on the inner side surface of the cavity.

The inventors of the present disclosure experimentally confirmed that by introducing the technical features to be described below, defects occurring in the encapsulation layer and the insulating layer may be suppressed, and a manufacture method for a packaging substrate having stable durability and electrical reliability may be provided, thereby completing the present disclosure.

Hereinafter, the present disclosure will be described in detail.

The manufacture method for a packaging substrate of the present disclosure comprises: a preparation step of preparing a preliminary substrate including a core layer in which a cavity portion including a device mounting space and an inner side surface of the cavity surrounding the device mounting space is formed; a surface treatment step of increasing surface energy of at least a portion of the inner side surface of the cavity; and an encapsulation layer forming step of forming an encapsulation layer surrounding at least a portion of the surface of the device with an encapsulation layer-forming composition, thereby manufacturing a packaging substrate.

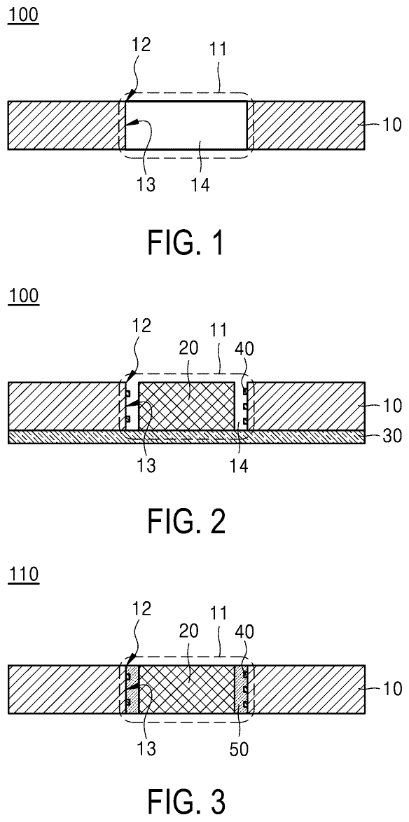

FIG. 1 is a cross-sectional view illustrating a preliminary substrate prepared through a preparation step of the present disclosure. Hereinafter, the present disclosure will be described with reference to FIG. 1.

### Preparation Step

The preliminary substrate (100) may include a core layer (10).

The core layer (10) may function as a support layer in the packaging substrate. The core layer (10) may be applied without limitation as long as it is used as a support layer in the field of packaging substrates. For example, the core layer (10) may be a glass substrate, a ceramic substrate, or an organic substrate.

In particular, the core layer (10) may be a glass substrate. When the glass substrate is applied as the core layer (10), it is advantageous for implementing fine patterns and may stably suppress the generation of parasitic elements.

The glass substrate may be, for example, an alkali borosilicate plate glass, an alkali-free borosilicate plate glass, or an alkali-free alkaline earth borosilicate plate glass, and may be applied as long as it is a plate glass applied to electronic components. The glass substrate may be an electronic device glass substrate, and for example, products manufactured by Schott, AGC, or Corning may be applied, but the present disclosure is not limited thereto.

The core layer (10) may include a through-via (not shown) penetrating the thickness direction of the core layer (10).

The through-via comprises an inner space (not shown) and an inner circumferential surface of the via (not shown) surrounding the inner space. The inner space means an empty space, and the inner circumferential surface of the via means a surface of the core layer (10) formed inside the through-via.

The through-via may have a diameter varying along the thickness direction of the core layer (10). The through-via may have a substantially uniform diameter along the thickness direction of the core layer (10).

A surface of the core layer (10) may include an upper surface and a side surface connected to the upper surface and formed along the thickness direction of the core layer (10). The surface of the core layer (10) may include a lower surface facing the upper surface.

That the side surface is formed along the thickness direction of the core layer (10) is interpreted to mean that at least part of the side surface forms a vertical angle with the upper surface of the core layer (10), and/or that at least a portion of the side surface forms an angle (inclined angle) other than 90 degrees with the upper surface.

The side surface may be a flat surface or a curved surface.

A thickness of the core layer (10) may be 100 μm or more. The thickness may be 200 μm or more. The thickness may be 300 μm or more. The thickness may be 3000 μm or less. The thickness may be 2000 μm or less. The thickness may be 1000 μm or less. In such a case, the core layer (10) may have mechanical properties suitable for application to a packaging substrate.

The core layer (10) may have a cavity portion (11) including a device mounting space (14) and an inner side surface (13) of the cavity surrounding the device mounting space (14).

The cavity portion (11) may be formed by being recessed at the upper surface side of the core layer (10). The cavity portion (11) may be formed by a portion of the upper surface side of the core layer (10) being recessed along the thickness direction of the core layer (10). The cavity portion (11) may be formed by penetrating through the thickness direction of the core layer (10).

The cavity portion (11) may include the device mounting space (14) and the inner side surface (13) of the cavity surrounding the device mounting space (14). The cavity portion (11) includes a cavity opening (12) disposed on the upper surface side of the core layer (10), an inner side surface (13) of the cavity connected to the cavity opening (12) and extending in the thickness direction of the core layer (10), and the inner space (14) surrounded by the inner side surface (13) of the cavity.

The cavity opening (12) may be disposed adjacent to the upper surface of the core layer (10). The cavity opening (12) may form an inner edge of the upper surface of the core layer (10).

That the inner side surface (13) of the cavity is formed to extend in the thickness direction of the core layer (10) is interpreted to mean that at least of a portion of the inner side surface (13) forms a vertical angle with the upper surface of the core layer (10), and/or that at least a portion of the inner side surface (13) forms an angle (inclined angle) other than 90 degrees with the upper surface.

The inner side surface (13) of the cavity may be a flat surface or a curved surface.

The preliminary substrate (100) may further include a cavity conductive layer (40) formed on the inner side surface (13) of the cavity. The cavity conductive layer (40) is a conductive layer disposed on the inner side surface (13) of the cavity to transmit an electrical signal in the packaging substrate. The cavity conductive layer (40) may be disposed in contact with the inner side surface (13) of the cavity, or another component may be disposed between the cavity conductive layer (40) and the inner side surface (13) of the cavity.

The inner side surface (13) of the cavity may include an exposed region exposed to the outside. The exposed region is a region of the inner side surface (13) of the cavity that is not covered by the cavity conductive layer (40).

A redistribution layer (not shown) may be formed on the inner side surface (13) of the cavity. The redistribution layer may include the cavity conductive layer (40) and an insulating layer (not shown) surrounding at least a portion of the cavity conductive layer (40).

In the preparation step, a core layer (10) in which the cavity conductive layer (40) has already been formed on the inner side surface (13) of the cavity may be prepared. In the preparation step, the cavity conductive layer (40) may be formed on the inner side surface (13) of the cavity.

A detailed description of the conductive layer, the insulating layer, and the redistribution layer will be given below, and thus omitted here.

The device mounting space (14) is a space in which a device portion is mounted. The device mounting space (14) may be an inner space formed by recessing the upper surface side of the core layer (10).

A description of the device portion will be given below, and thus omitted here.

### Surface Treatment Step

In the present disclosure, in the surface treatment step, surface energy of at least a portion of the inner side surface (13) of the cavity may be increased. In the surface treatment step, surface energy of the cavity conductive layer (40) and the exposed region may be increased. Through this, affinity for the encapsulation layer-forming composition in the region where the encapsulation layer is formed may be effectively increased, and the occurrence of an undulation phenomenon in the insulating layer caused by defects in the encapsulation layer may be effectively suppressed. In particular, even in the cavity portion (11) in which the cavity conductive layer (40) is formed on the inner side surface (13) of the cavity, the surface treatment step of the present disclosure may be effective in forming an encapsulation layer with suppressed voids.

In the surface treatment step, at least a portion of the inner side surface (13) of the cavity may be plasma-treated. In the surface treatment step, the cavity conductive layer (40) and the exposed region of the inner side surface (13) of the cavity may be plasma-treated together. Through plasma treatment, a plurality of functional groups having hydrophilicity may be formed on the surface of the cavity conductive layer (40) and the like. Through this, the hydrophilic encapsulation layer-forming composition may be smoothly filled without voids into a space formed between the device portion mounted in the cavity portion (11) and the inner side surface (13) of the cavity.

In the surface treatment step, an ambient gas may be introduced. In the surface treatment step, the ambient gas may serve as a plasma generating gas.

In the surface treatment step, plasma power may be 50 W to 1500 W. The plasma power may be 100 W or more. The plasma power may be 150 W or more. The plasma power may be 200 W or more. The plasma power may be 1200 W or less. The plasma power may be 1000 W or less. In such a case, excessive damage to the cavity conductive layer (40) may be suppressed, and surface properties of the inner side surface (13) of the cavity and the like may be efficiently controlled.

The surface treatment step may be carried out for 15 seconds to 60 seconds. The surface treatment step may be carried out for 17 seconds or more. The surface treatment step may be carried out for 50 seconds or less. The surface treatment step may be carried out for 40 seconds or less. In such a case, the inner side surface (13) of the cavity and the like, having sufficiently improved affinity for the encapsulation layer-forming composition, may be efficiently provided.

The ambient gas may include 50 vol % or more of oxygen gas. The ambient gas may include 60 vol % or more of oxygen gas. The ambient gas may include 70 vol % or more of oxygen gas. The ambient gas may include 100 vol % or less of oxygen gas. In such a case, the surface energy of the inner side surface (13) of the cavity and the like may be controlled to fall within a predetermined range in the present disclosure.

In the surface treatment step, an ambient gas with a controlled flow rate may be introduced. Through this, the inner side surface (13) of the cavity and the like may have surface energy suitable for forming an encapsulation layer. At the same time, it may prevent an adhesive film (30) fixing the device portion (20) from having excessively high affinity for the encapsulation layer, thereby preventing residual adhesive material of the adhesive film (30) from excessively remaining on the surface of the encapsulation layer.

In the surface treatment step, plasma treatment may be performed with 50 sccm to 1000 sccm of ambient gas. In the surface treatment step, plasma treatment may be performed with 100 sccm or more of ambient gas. In the surface treatment step, plasma treatment may be performed with 200 sccm or more of ambient gas. In the surface treatment step, plasma treatment may be performed with 300 sccm or more of ambient gas. In the surface treatment step, plasma treatment may be performed with 800 sccm or less of ambient gas. In the surface treatment step, plasma treatment may be performed with 600 sccm or less of ambient gas. In the surface treatment step, plasma treatment may be performed with 450 sccm or less of ambient gas. In the surface treatment step, plasma treatment may be performed with 300 sccm or less of ambient gas. In the surface treatment step, plasma treatment may be performed with 200 sccm or less of ambient gas. In such a case, while smoothly forming the encapsulation layer, occurrence of defects in the insulating layer caused by adhesive material may be stably suppressed.

In the surface treatment step, a contact angle of water with respect to the inner side surface (13) of the cavity may be adjusted to 60° or less. In the surface treatment step, the contact angle of water with respect to the inner side surface (13) of the cavity may be adjusted to 40° or less. In the surface treatment step, the contact angle of water with respect to the inner side surface (13) of the cavity may be adjusted to 30° or less. In the surface treatment step, the contact angle of water with respect to the inner side surface (13) of the cavity may be adjusted to 25° or less. In the surface treatment step, the contact angle of water with respect to the inner side surface (13) of the cavity may be adjusted to 20° or less. In the surface treatment step, the contact angle of water with respect to the inner side surface (13) of the cavity may be adjusted to 5° or more.

In the surface treatment step, a contact angle of water with respect to the surface of the cavity conductive layer (40) may be adjusted to 60° or less. In the surface treatment step, the contact angle of water with respect to the surface of the cavity conductive layer (40) may be adjusted to 40° or less. In the surface treatment step, the contact angle of water with respect to the surface of the cavity conductive layer (40) may be adjusted to 30° or less. In the surface treatment step, the contact angle of water with respect to the surface of the cavity conductive layer (40) may be adjusted to 25° or less. In the surface treatment step, the contact angle of water with respect to the surface of the cavity conductive layer (40) may be adjusted to 20° or less. In the surface treatment step, the contact angle of water with respect to the surface of the cavity conductive layer (40) may be adjusted to 5° or more.

In such a case, defects caused by differences in surface energy properties between the encapsulation layer-forming composition and other components disposed in the cavity portion may be effectively suppressed.

The contact angle is measured using a surface analyzer. Specifically, water is dropped on the inner side surface of the cavity or the surface of the cavity conductive layer, and the contact angle is measured with the surface analyzer.

### Device Mounting Step

FIG. 2 is a cross-sectional view illustrating a preliminary substrate prepared through a device mounting step of the present disclosure. Hereinafter, the present disclosure will be described with reference to FIG. 2.

The descriptions of the core layer (10) and the cavity portion (11), etc., in FIG. 1 are equally applicable here. The following will focus on the differences.

The manufacture method for a packaging substrate of the present disclosure may further include a device mounting step of mounting a device portion (20) in the cavity portion (11) after the surface treatment step. The present disclosure may perform fixing of the device portion (20) through an adhesive film (30) after completing the surface treatment step. Through this, it may be effectively suppressed that surface energy of adhesive material included in the adhesive film (30) is excessively increased in the surface treatment step, which would otherwise hinder peeling of the adhesive film (30) or cause the adhesive material to remain on the surface of the encapsulation layer.

The preliminary substrate (100) may further include the device portion (20) disposed in the cavity portion (11). The device portion (20) may be disposed in the device mounting space (14).

The device portion (20) may be fixed within the cavity portion (11) by the adhesive film (30).

The adhesive film (30) may be applied without limitation as long as it is a film used for device fixing in the packaging field. For example, the adhesive film (30) may be a polyimide tape.

The device portion (20) may be a device itself, or may be a device package. The device package is one or more devices packaged by a device insulating material. The device insulating material may surround at least a portion of the surface of the device. The device insulating material may fix one or more devices in the device package and may impart insulation to a desired region in the device package.

The device may include not only semiconductor devices such as a CPU, GPU, and memory chip but also a capacitor device, a transistor device, an impedance device, and other modules. That is, as long as it is a semiconductor device mounted on a semiconductor device, it may be applied without limitation as the device.

The device insulating material may include a material capable of appropriately fixing the device while preventing electrical short circuit. The device insulating material may include, for example, any one selected from the group consisting of epoxy-based resin, polyimide-based resin, polyurethane-based resin, polyester-based resin, acrylate-based resin, polyamide-based resin, and a combination thereof.

The device portion (20) may include a side surface. The side surface of the device portion (20) may be disposed to face apart from a portion of the inner side surface of the cavity.

In the device mounting step, a preliminary substrate (100) in which the gap aspect ratio Arg of Equation 1 below is 30 or less may be prepared.

$$Arg = \frac{e h}{g} \qquad [ Equation 1 ]$$

In Equation 1, eh is the height of the device portion (20), and g is the minimum distance between a first point located on the side surface of the device portion (20) and a second point located on the cavity opening (12).

The present disclosure may control the Arg value of the preliminary substrate (100) to adjust the shape of a space formed between the device portion (20) and the inner side surface (13) of the cavity. Through this, an encapsulation layer-forming composition having a viscosity of a certain level or more may be easily dispensed into the space, thereby efficiently suppressing the formation of voids in the encapsulation layer.

The Arg value of the preliminary substrate (100) may be 30 or less. The Arg value may be 25 or less. The Arg value may be 20 or less. The Arg value may be 15 or less. The Arg value may be 10 or less. The Arg value may be 7 or less. The Arg value may be 0.1 or more. The Arg value may be 0.5 or more. The Arg value may be 1 or more. In such a case, an encapsulation layer-forming composition including filler may sufficiently fill the space formed in the cavity portion (11).

The g value may be 20 μm to 500 μm. The g value may be 50 μm or more. The g value may be 100 μm or more. The g value may be 400 μm or less. The g value may be 300 μm or less.

The eh value may be 300 μm to 600 μm. The eh value may be 350 μm or more. The eh value may be 400 μm or more. The eh value may be 550 μm or less.

In such a case, the encapsulation layer-forming composition may be easily filled into the space formed between the inner side surface (13) of the cavity and the device portion (20). In addition, the shape and volume of the formed encapsulation layer may be controlled to contribute to suppressing defects such as wrinkling in the insulating layer formed on the encapsulation layer.

### Encapsulation Layer Forming Step

In the encapsulation layer forming step, an encapsulation layer surrounding at least a portion of the device portion (20) is formed with an encapsulation layer-forming composition. In the encapsulation layer forming step, the encapsulation layer-forming composition may be cured to form the encapsulation layer.

The encapsulation layer forming step may include a placement process of placing the encapsulation layer-forming composition between the inner side surface (13) of the cavity and one side surface of the device portion (20), and a curing process of curing the encapsulation layer-forming composition to form the encapsulation layer.

### Placement Process

The encapsulation layer-forming composition may include an epoxy-based resin and a curing agent.

In the present disclosure, by applying an epoxy-based resin to the encapsulation layer-forming composition, controlled elasticity may be imparted to the encapsulation layer. Through this, while the encapsulation layer sufficiently protects the device portion (20), the encapsulation layer may stably support an insulating layer formed on the encapsulation layer.

The epoxy-based resin may include two or more epoxy groups. The epoxy-based resin may be any one selected from the group consisting of bisphenol A type epoxy resin, brominated bisphenol A type epoxy resin, bisphenol F type epoxy resin, biphenyl type epoxy resin, novolac type epoxy resin, alicyclic epoxy resin, naphthalene type epoxy resin, silicone epoxy copolymer resin, or a combination thereof.

The weight average molecular weight of the epoxy-based resin may be 1,000 g/mol or less. The weight average molecular weight may be 800 g/mol or less. The weight average molecular weight may be 600 g/mol or less. The weight average molecular weight may be 100 g/mol or more.

The curing agent of the present disclosure is not limited as long as it is a compound that may function as a curing agent of the epoxy-based resin. For example, the curing agent may be an acid anhydride-based curing agent, an aromatic amine, a phenol resin, or an imidazole-based compound.

The present disclosure may apply 0.3 equivalent or more of a curing agent per 1 equivalent of an epoxy group in the epoxy-based resin. The present disclosure may apply 0.5 equivalent or more of a curing agent per 1 equivalent of an epoxy group in the epoxy-based resin. The present disclosure may apply 0.7 equivalent or more of a curing agent per 1 equivalent of an epoxy group in the epoxy-based resin. The present disclosure may apply 2 equivalents or less of a curing agent per 1 equivalent of an epoxy group in the epoxy-based resin. The present disclosure may apply 1.5 equivalents or less of a curing agent per 1 equivalent of an epoxy group in the epoxy-based resin.

The encapsulation layer-forming composition may further include a filler. The filler may contribute to the encapsulation layer-forming composition having viscosity within a predetermined range in the present disclosure, and may help the encapsulation layer have physical properties suitable for the packaging substrate.

The filler may include inorganic particles. The filler may be inorganic particles. For example, the filler may include silica, titania, or alumina.

An average particle diameter of the filler may be 150 nm or less. The average particle diameter may be 120 nm or less. The average particle diameter may be 100 nm or less. The average particle diameter may be 80 nm or less. The average particle diameter may be 10 nm or more. The average particle diameter may be 30 nm or more. In such a case, the encapsulation layer-forming composition may have viscosity characteristics suitable for cavity filling, and may help the encapsulation layer have desired mechanical properties. In addition, it may be easy to implement a conductive layer having fine pitch on the encapsulation layer.

The encapsulation layer-forming composition may include 45 wt % or more and 80 wt % or less of filler.

The present disclosure may adjust the filler content in the encapsulation layer-forming composition to fall within a predetermined range in the present disclosure. Through this, the encapsulation layer-forming composition may have flow characteristics suitable for smoothly filling the space formed between the device portion (20) and the inner side surface (13) of the cavity, and the formed encapsulation layer may stably protect the device from external impact and thermal shock.

The encapsulation layer-forming composition may include 45 wt % or more of filler. The encapsulation layer-forming composition may include 50 wt % or more of filler. The encapsulation layer-forming composition may include 75 wt % or less of filler. The encapsulation layer-forming composition may include 70 wt % or less of filler. In such a case, the composition may have flow characteristics suitable for filling the cavity portion (11) in which the device portion (20) is mounted. In addition, the composition may stably fix the device portion (20) and the insulating layer formed on the encapsulation layer within the cavity portion (11), and may form an encapsulation layer that does not apply excessive stress to the core layer (10) during a high-temperature manufacturing process.

The encapsulation layer-forming composition may include a solvent. The solvent is not limited as long as it may be typically applied in the technical field. For example, the solvent may include aliphatic hydrocarbon solvents, aromatic hydrocarbon solvents, ethers, or esters.

The encapsulation layer-forming composition may further include an additive. The additive is not limited as long as it may be typically applied in the technical field. For example, the additive may include a defoamer, a coupling agent, a flame retardant, or a surfactant.

In the placement process, the encapsulation layer-forming composition may be melt-mixed and charged into a region where the encapsulation layer is to be formed. The melt-mixed encapsulation layer-forming composition may be placed through an injection device. The melt-mixed encapsulation layer-forming composition may be placed through a heating cylinder.

The present disclosure may control the temperature of the heating cylinder within a predetermined range in the placement process. Through this, the encapsulation layer-forming composition may have melt viscosity suitable for filling narrow gaps, thereby suppressing the formation of voids in the encapsulation layer.

The temperature of the heating cylinder refers to the temperature measured at the tip of the heating cylinder.

In the placement process, the temperature of the heating cylinder may be 40° C. to 70° C. The temperature may be 45° C. or more. The temperature may be 50° C. or more. The temperature may be 65° C. or less. The temperature may be 60° C. or less. In such a case, the encapsulation layer-forming composition may sufficiently fill the empty space in the cavity portion (11).

The present disclosure may apply an encapsulation layer-forming composition having controlled viscosity at 25° C. The encapsulation layer-forming composition having viscosity controlled within a predetermined range in the present disclosure may have flow characteristics suitable for filling a space having a complex shape in the cavity portion (11) in the placement process. In addition, the encapsulation layer formed through curing of the composition may have thermal expansion properties suitable for application to a substrate having high hardness.

A viscosity of the encapsulation layer-forming composition at 25° C. may be 12,000 cps to 38,000 cps. The viscosity may be 15,000 cps or more. The viscosity may be 18,000 cps or more. The viscosity may be 20,000 cps or more. The viscosity may be 35,000 cps or less. The viscosity may be 32,000 cps or less. The viscosity may be 30,000 cps or less. The viscosity may be 28,000 cps or less. In such a case, the encapsulation layer-forming composition may be smoothly charged into the empty space in the cavity portion, thereby helping suppress the occurrence of defects in the encapsulation layer.

The viscosity of the encapsulation layer-forming composition at 25° C. is measured with a viscometer after adjusting the temperature of the composition to 25° C.

### Curing Process

FIG. 3 is a cross-sectional view illustrating a packaging substrate manufactured through the manufacture method for a packaging substrate of the present disclosure. Hereinafter, the present disclosure will be described with reference to FIG. 3.

The descriptions of the core layer (10), the device portion (20), and the cavity portion (11), etc., in FIGS. 1 and 2 are equally applicable here. The following will focus on the differences.

In the curing process, the encapsulation layer-forming composition placed in a region for forming the encapsulation layer may be cured to form an encapsulation layer (50). The encapsulation layer-forming composition may be cured by heating to form the encapsulation layer (50).

In the curing process, the heat treatment temperature may be 120° C. or more. The heat treatment temperature may be 130° C. or more. The heat treatment temperature may be 140° C. or more. The heat treatment temperature may be 250° C. or less. The heat treatment temperature may be 230° C. or less. The heat treatment temperature may be 200° C. or less.

In the curing process, the heat treatment time may be 30 minutes or more. The heat treatment time may be 40 minutes or more. The heat treatment time may be 50 minutes or more. The heat treatment time may be 200 minutes or less. The heat treatment time may be 180 minutes or less. The heat treatment time may be 150 minutes or less.

In such a case, the curing reaction may stably proceed within the encapsulation layer-forming composition, thereby helping form the encapsulation layer (50) having excellent physical properties.

In the packaging substrate (110) manufactured through the encapsulation layer forming step, the encapsulation layer (50) may be formed to surround at least a portion of the device portion (20). The encapsulation layer (50) may surround at least a portion of one side surface of the device portion (20). The encapsulation layer (50) may surround all side surfaces of the device portion (20). The encapsulation layer (50) may surround at least a portion of an upper surface of the device portion (20). The encapsulation layer (50) may surround the upper surface of the device portion (20). The encapsulation layer (50) may surround at least a portion of the upper surface and the side surface of the device portion (20). The encapsulation layer (50) may surround at least a portion of the overall surface of the device portion (20).

At least a portion of the encapsulation layer (50) may be disposed in contact with the surface of the device portion (20). The encapsulation layer (50) may be disposed in contact with the surface of the device portion (20). The encapsulation layer (50) may be disposed apart from the surface of the device portion (20).

In the packaging substrate (110) of the present disclosure, an encapsulation layer (50) in which an excessive empty space is not formed may be formed. Through this, the encapsulation layer (50) may stably support and fix the device portion (20), and in implementing a redistribution layer on and/or under the encapsulation layer (50), defects such as undulation in the redistribution layer may be stably suppressed.

After forming the encapsulation layer (50), the adhesive film (30) may be peeled and removed.

Step after Encapsulation Layer Forming Step

The manufacture method for a packaging substrate of the present disclosure may further include a redistribution layer forming step after the encapsulation layer forming step.

In the redistribution layer forming step, a redistribution layer may be formed on the core layer (10) and the encapsulation layer (50). In the redistribution layer forming step, a redistribution layer may be formed under the core layer (10) and the encapsulation layer (50).

The redistribution layer forming step may include a process of forming a conductive layer and a process of forming an insulating layer.

In the process of forming a conductive layer, the conductive layer may be formed on the surface of the glass core (10) and/or on the insulating layer. In the case of forming a conductive layer on the mounted device, an insulating layer may first be formed on the upper surface of the device, and then the conductive layer may be formed on the insulating layer.

The conductive layer may be formed by a dry method or a wet method.

The dry method is a method of forming a seed layer by sputtering on a region where the conductive layer is to be disposed, and forming the conductive layer by plating on the region in which the seed layer is formed. When forming the seed layer, metals such as titanium, chromium, or nickel may be sputtered, and these metals and copper may be sputtered together. Through sputtering, an anchor effect in which the surface on which the conductive layer is disposed and the deposited metal particles interact may appear, thereby improving adhesion of the conductive layer.

The wet method is a method of performing metal plating after treating a primer on a portion where a conductive layer needs to be formed. The primer may include a compound having a functional group such as an amine. Depending on the degree of adhesion intended, the primer may include both a compound having a functional group such as an amine and a silane coupling agent. When a silane coupling agent is applied, a primer layer may be formed by pretreating a surface to be treated with the silane coupling agent and then coating the pretreated region with a compound having an amine group.

After forming a seed layer or a primer layer, a conductive layer may be formed by plating metal. Copper plating may be applied in forming the conductive layer, but the present disclosure is not limited thereto. Before plating metal, a portion in the seed layer or the primer layer where the conductive layer does not need to be formed may be inactivated, or a portion where the conductive layer needs to be formed may be activated, and then plating may be performed. As methods of activation or inactivation treatment, light irradiation treatment such as irradiating with a laser of a specific wavelength, or chemical treatment may be applied. However, even without applying activation or inactivation treatment, the conductive layer may be patterned by etching after performing metal plating according to a predesigned shape.

In the redistribution layer forming step, an insulating layer may be formed to surround at least a portion of the conductive layer. The insulating layer may be formed to surround at least a portion of the upper surface of the conductive layer. The insulating layer may be formed to surround at least a portion of the side surface of the conductive layer.

The insulating layer and the conductive layer may be disposed in a mixed state on the core layer (10). The conductive layer having a pattern shape may be formed in a form embedded in the insulating layer.

The insulating layer may be applied as long as it may be used as an insulating layer for a semiconductor device or a packaging substrate. For example, the insulating layer may be an epoxy-based resin including a filler. The insulating layer may, for example, be formed by a build-up layer material such as ABF (Ajinomoto Build-up Film) of Ajinomoto Co., or an undercoat material, but the present disclosure is not limited thereto.

The insulating layer may be formed by laminating an uncured or semi-cured insulating film and then curing it.

In the redistribution layer forming step, by completing the formation of a redistribution layer having a predesigned structure on and/or under the core layer (10), a packaging substrate (110) may be prepared.

### Other Step

If necessary, an upper terminal and the like may be further formed on the upper part and/or side of the packaging substrate (110), and bumps may be further formed on the lower part of the packaging substrate (110). The bumps may be disposed in a predetermined shape under a redistribution layer disposed below the core layer (10). For example, the bumps may be disposed on a portion of the lower surface of the packaging substrate (110) so as to contact a main board or the like.

Hereinafter, the present disclosure will be described in more detail through specific embodiments. The following embodiments are merely examples for understanding the present disclosure, and the scope of the present disclosure is not limited thereto.

### Manufacturing Example: Formation of Packaging Substrate

Experimental Example 1: A glass substrate having a thickness of 510 μm and a full cavity of 40 mm to 60 mm in width and 40 mm to 60 mm in length was prepared. A device having a height of 480 μm was placed in the cavity to prepare a preliminary substrate. The distance between the inner side surface of the cavity and the device was applied as 150 μm, and a polyimide tape was attached to the lower surface of the glass substrate to fix the device.

An empty space formed between the device and the inner side surface of the cavity was filled with encapsulation layer-forming composition U8410-302SNS8AG of Namics Co. through injection equipment. The viscosity of the encapsulation layer-forming composition at 25° C. was 25,000 cps, and the temperature of the cylinder tip during filling was applied as 40° C. to 60° C.

After completing the filling, the substrate was heat-treated at 150° C. to 160° C. for 1 hour to 2 hours to form an encapsulation layer, and the polyimide tape was peeled off to manufacture a packaging substrate.

Experimental Example 2: A preliminary substrate in which the device portion was fixed under the same conditions as in Experimental Example 1 was prepared. The surface of the preliminary substrate was plasma-treated. Plasma power of 6000 W was applied, 500 sccm of oxygen gas was introduced as ambient gas, and plasma treatment was carried out for 20 seconds.

After completing the plasma treatment, an encapsulation layer was formed under the same conditions as in Experimental Example 1 to manufacture a packaging substrate.

Experimental Example 3: A packaging substrate was manufactured under the same conditions as in Experimental Example 2, except that plasma power of 3000 W was applied.

Experimental Example 4: A packaging substrate was manufactured under the same conditions as in Experimental Example 2, except that plasma power of 1000 W was applied.

Experimental Example 5: A packaging substrate was manufactured under the same conditions as in Experimental Example 2, except that plasma power of 300 W was applied.

Experimental Example 6: A packaging substrate was manufactured under the same conditions as in Experimental Example 5, except that the flow rate of the ambient gas was applied as 100 sccm.

Experimental Example 7: The surface of the glass substrate applied in Experimental Example 1 was plasma-treated. Plasma power of 6000 W was applied, 500 sccm of oxygen gas was introduced as ambient gas, and plasma treatment was carried out for 20 seconds.

After plasma treatment, a device having a height of 480 μm was placed in the cavity to prepare a preliminary substrate. The distance between the inner side surface of the cavity and the device was applied as 150 μm, and a polyimide tape was attached to the lower surface of the glass substrate to fix the device.

After fixing the device, an encapsulation layer was formed under the same conditions as in Experimental Example 1 to manufacture a packaging substrate.

Experimental Example 8: A packaging substrate was manufactured under the same conditions as in Experimental Example 7, except that plasma power of 3000 W was applied.

Experimental Example 9: A packaging substrate was manufactured under the same conditions as in Experimental Example 7, except that plasma power of 1000 W was applied.

The process conditions of each Experimental Example are described in Table 1 below.

### Evaluation Example: Evaluation of Water Contact Angle on Glass Substrate Surface

In the manufacturing process of the packaging substrate for each Experimental Example, immediately before filling the cavity portion with an encapsulation layer-forming composition, the water contact angle on the inner side surface of the cavity was measured using a surface analyzer. Specifically, water was dropped onto the inner side surface of the cavity, and the contact angle was measured using the surface analyzer.

The measured values for each Experimental Example are described in Table 2 below.

### Evaluation Example: Evaluation of Void Formation in Encapsulation Layer

In the packaging substrates of Experimental Examples 2 to 9, whether voids occurred in the encapsulation layer was observed with an optical microscope and TEM (Transmission Electron Microscope).

When voids were not found in the encapsulation layer, it was evaluated as P, and when voids were found, it was evaluated as F.

The evaluation results for each Experimental Example are described in Table 2 below.

### Evaluation Example: Evaluation of Ink Leakage

The bottom surface of the packaging substrates of Experimental Examples 2 to 9 was observed with an optical microscope, and the extent to which the encapsulation layer-forming composition leaked beyond the inner side surface of the cavity was measured. Specifically, when observed from the bottom surface of the packaging substrate, a first point located at the edge formed where the inner side surface of the cavity and the bottom surface of the packaging substrate meet was specified. From the first point, a straight line was drawn in the direction perpendicular to the edge, and a second point where the straight line met the edge of the encapsulation layer formed on the bottom surface of the packaging substrate was specified. The distance between the first point and the second point was measured. The maximum value of the distance measurement was calculated and defined as the ink leakage distance of the corresponding Experimental Example.

The measured values for each Experimental Example are described in Table 2 below.

### Evaluation Example: Evaluation of Peelability of Polyimide Tape

In the manufacturing process of the packaging substrates of Experimental Examples 4 and 6 to 9, after completing the formation of the encapsulation layer, the adhesion force between the encapsulation layer and the polyimide tape was measured using a Condor Sigma bond tester from XYZ TEC according to a 180° peel test. The measurement speed (peel speed) was set to 10 mm/s, and the measurement distance (peel distance) was set to 70 mm.

The measured values for each Experimental Example are described in Table 2 below.

### Evaluation Example: Evaluation of Residual Adhesive Material

The bottom surface of the packaging substrates of Experimental Examples 4 and 6 to 9 was observed with an optical microscope and TEM (Transmission Electron Microscope) to check whether the adhesive material of the polyimide film remained on the bottom surface of the packaging substrate. When adhesive material did not remain, it was evaluated as P, and when adhesive material remained, it was evaluated as F.

The evaluation results for each Experimental Example and Comparative Example are described in Table 2 below.

TABLE 1

| | Whether | Whether the | | | |
|---|---|---|---|---|---|
| | plasma | device is | | Ambient | Plasma |
| | treatment | fixed after | Plasma | gas flow | treatment |
| | is | plasma | power | rate | time |
| | performed | treatment | (W) | (sccm) | (seconds) |
| Experimental | X | — | — | — | — |
| Example 1 | | | | | |
| Experimental | ◯ | X | 6000 | 500 | 20 |
| Example 2 | | | | | |
| Experimental | ◯ | X | 3000 | 500 | 20 |
| Example 3 | | | | | |
| Experimental | ◯ | X | 1000 | 500 | 20 |
| Example 4 | | | | | |
| Experimental | ◯ | X | 300 | 500 | 20 |
| Example 5 | | | | | |
| Experimental | ◯ | X | 300 | 100 | 20 |
| Example 6 | | | | | |
| Experimental | ◯ | ◯ | 6000 | 500 | 20 |
| Example 7 | | | | | |
| Experimental | ◯ | ◯ | 3000 | 500 | 20 |
| Example 8 | | | | | |
| Experimental | ◯ | ◯ | 1000 | 500 | 20 |
| Example 9 | | | | | |

TABLE 2

| | | | | | Evaluation of |
|---|---|---|---|---|---|
| | | Evaluation | Ink leakage | Peel strength | residual |
| | Contact | of void | evaluation | of polyimide | adhesive |
| | angle (°) | formation | (mm) | tape (gf/cm²) | material |
| Experimental | 110 | — | — | — | — |
| Example 1 | | | | | |
| Experimental | 15.6 | P | 10 | — | — |
| Example 2 | | | | | |
| Experimental | 19.7 | P | 6 | — | — |
| Example 3 | | | | | |
| Experimental | 22.1 | P | 0.5 | 400 | F |
| Example 4 | | | | | |
| Experimental | 26.6 | P | 6 | — | — |
| Example 5 | | | | | |
| Experimental | 29.1 | P | 2 | 450 | F |
| Example 6 | | | | | |
| Experimental | 17.9 | P | <0.5 | <150 | P |
| Example 7 | | | | | |
| Experimental | 18.2 | P | <0.5 | <150 | P |
| Example 8 | | | | | |
| Experimental | 23.5 | P | <0.5 | <150 | P |
| Example 9 | | | | | |

From the results of the contact angle measurement described in Table 2, in the case of Experimental Example 1 without applying plasma treatment, a value of 100° or more was shown, whereas Experimental Examples 2 to 9 with plasma treatment showed values of 30° or less.

In the evaluation of void formation, Experimental Examples 2 to 9 with plasma treatment did not show voids.

In the evaluation of ink leakage, Experimental Examples 7 to 9, in which device fixation was carried out after plasma treatment, were measured to be less than 0.5 mm, whereas among Experimental Examples 2 to 6, in which plasma treatment was carried out after device fixation, Experimental Examples 2, 3, and 5 were measured to be 6 mm or more.

In the evaluation of peel strength of polyimide tape, Experimental Examples 7 to 9, in which device fixation was carried out after plasma treatment, were measured to have peel strength of less than 150 gf/cm², and no residual adhesive material was found. In contrast, Experimental Examples 4 and 6, in which plasma treatment was carried out after device fixation, showed values of 400 gf/cm² or more in peel strength, and residual adhesive material was found.

Although the preferred embodiments of the present invention have been described in detail above, the scope of rights of the present invention is not limited thereto, and various modifications and improved forms using the basic concept of the present invention defined in the following claims by those skilled in the art also belong to the scope of rights of the present invention.

### EXPLANATION OF REFERENCE NUMERALS

100: Preliminary substrate
110: Packaging substrate
10: Core layer
11: Cavity portion
12: Cavity opening
13: Inner side surface of the cavity
14: Device mounting space
20: Device portion
30: Adhesive film
40: Cavity conductive layer
50: Encapsulation layer

1. A method of manufacturing a packaging substrate, comprising:
a preparation step of preparing a preliminary substrate which comprises a core layer in which a cavity portion comprises a device mounting space and an inner side surface of the cavity surrounding the device mounting space;
a surface treatment step of increasing surface energy of at least a portion of the inner side surface of the cavity; and
an encapsulation layer forming step of forming an encapsulation layer which comprises surrounding at least a portion of the surface of the device portion with an encapsulation layer-forming composition.

2. The method of manufacturing a packaging substrate of claim 1,
wherein the preliminary substrate further comprises a cavity conductive layer formed on the inner side surface of the cavity,
wherein the inner side surface of the cavity comprises an exposed region not covered with the cavity conductive layer, and
wherein in the surface treatment step, surface energies of the cavity conductive layer and the exposed region are increased.

3. The method of manufacturing a packaging substrate of claim 1,
wherein in the surface treatment step, at least a portion of the inner side surface of the cavity is plasma treated.

4. The method of manufacturing a packaging substrate of claim 3,
wherein in the surface treatment step, an ambient gas comprises 50 volume % or more of oxygen gas.

5. The method of manufacturing a packaging substrate of claim 3,
wherein in the surface treatment step, plasma power is 50 W to 1500 W.

6. The method of manufacturing a packaging substrate of claim 3,
wherein the surface treatment step is performed for 15 seconds to 60 seconds.

7. The method of manufacturing a packaging substrate of claim 3,
wherein in the surface treatment step, plasma treatment is performed with an ambient gas of 50 sccm to 1000 sccm.

8. The method of manufacturing a packaging substrate of claim 1,
wherein in the surface treatment step, a contact angle of water with respect to the inner side surface of the cavity is adjusted to 60° or less.

9. The method of manufacturing a packaging substrate of claim 1,
further comprising a device portion mounting step which comprises mounting a device portion on the cavity portion after the surface treatment step is completed.

10. The method of manufacturing a packaging substrate of claim 9,
wherein the device portion comprises a side surface disposed spaced apart from the inner side surface of the cavity,
and a gap aspect ratio arg of equation 1 below is 30 or less:
$$Arg = \frac{e h}{g} \qquad [ Equation 1 ]$$
in equation 1, eh is a height of the device portion, and g is a minimum distance between a first point located on a side surface of the device portion and a second point located on the inner side surface of the cavity.

11. The method of manufacturing a packaging substrate of claim 10,
wherein the value of g is 20 μm to 500 μm.

12. The method of manufacturing a packaging substrate of claim 1,
wherein viscosity of the encapsulation layer-forming composition at 25° C. is 12,000 cps to 38,000 cps.

13. The method of manufacturing a packaging substrate of claim 1,
wherein the encapsulation layer-forming composition comprises 45 wt % or more and 80 wt % or less of filler.
